(19) United States
(12) Patent Application Publication
(10) Pub. No.: US 2026/0058445 A1
(43) Pub. Date: Feb. 26, 2026

(54) ELECTRICAL CIRCUIT SWITCH FOR CLUSTER NETWORKS

(71) Applicant: NVIDIA Corporation, Santa Clara, CA (US)

(72) Inventor: William James Dally, Incline Village, NV (US)

(21) Appl. No.: 18/813,349

(22) Filed: Aug. 23, 2024

(51) Int. Cl. H02B 1/34; H05K 7/14

(52) U.S. Cl. CPC H02B 1/34; H05K 7/1492

(57) ABSTRACT

Embodiments of the present disclosure relate to an electrical circuit switch for cluster networks. In an embodiment, a cluster network is implemented using NV-link. Signals are electrically transmitted between different racks that each include at least one electrical circuit switch (ECS). In contrast to conventional systems, the ECS transmits signals over wires without requiring optical transceivers to convert between optical-based signaling (light) and electrical-based signaling (current). The ECS operates as a repeater, amplifying and routing the electrical signals to enable transmission over distances greater than a meter, enabling electrical signaling to be used to construct networked clusters of processors across multiple rack enclosures. The ECS includes a plurality of input ports and a plurality of output ports, where each input port may be coupled via a repeater and multiplexer to any one of the output ports, providing a dedicated point-to-point communication path or link. Configuration of the connections between input ports and output ports may be programmed.

### BACKGROUND

The maximum bandwidth of electrically connected signaling, such as provided by an electrical cable, decreases with increasing cable length due to signal attenuation caused by the skin effect and dielectric absorption. At high-performance signaling rates (100-200 Gb/s) electrically connected signaling over electrical paths (conductive wires) are typically limited to distances of about a half meter on circuit boards and 1.5 meters in cables. Beyond these distances, the signaling rate is reduced. Although electrical signaling is common within a rack (cabinet or enclosure) containing multiple circuit boards each populated with processors, connections between different racks typically rely on fiber optic connections which are expensive (10× compared with electrical-based connections), unreliable, and consume excessive power (5× vs electrical). There is a need for addressing these issues and/or other issues associated with the prior art.

### SUMMARY

Embodiments of the present disclosure relate to an electrical circuit switch for cluster networks. In an embodiment, as the cluster networks are implemented using NV-link. Systems and methods are disclosed for electrically transmitting signals between different racks that each include at least one electrical circuit switch (ECS). In contrast to conventional systems, the ECS transmits signals over wires without requiring optical transceivers to convert between optical-based signaling (light) and electrical-based signaling (current). The ECS operates as a repeater, amplifying and routing the electrical signals to enable transmission over distances greater than a meter, enabling electrical signaling to be used to construct networked clusters of processors across multiple rack enclosures. In an embodiment, the ECS includes a plurality of input ports and a plurality of output ports, where each input port may be coupled via a multiplexer and repeater to any one of the output ports, providing a dedicated point-to-point communication path or link. Configuration of the connections between input ports and output ports may be programmed. The network maybe incrementally expanded without physically rewiring connections between existing rack enclosures. Spare processors within an enclosure may be configured to replace defective processors without physically rewiring connections.

In an embodiment, the method includes a system and method for configuring electrical circuit switches within a rack system including at least a first group of processors within a first enclosure and a second group of processors within a second enclosure, the first group of processors and the second group of processors each including at least one processor, the method comprising: defining a first cluster that includes the first group of processors and a subset of the second group of processors. A first electrical circuit switch (ECS) within the first enclosure and a second ECS within the second enclosure are configured to directly couple global connections between the first group and the subset, providing dedicated and independent communication paths between each one of the processors in the first cluster and other processors in the first cluster. A signal is electronically transmitted from a first processor in the first group to a second processor in the subset through an electrical connection comprising one path of the dedicated and independent communication paths directly from the first ECS to the second ECS.

### BRIEF DESCRIPTION OF THE DRAWINGS

The present systems and methods for an electrical circuit switch for cluster networks are described in detail below with reference to the attached drawing figures, wherein:

FIG. 1A illustrates a block diagram of an example ECS cluster network system suitable for use in implementing some embodiments of the present disclosure.

FIG. 1B illustrates another block diagram of an example ECS cluster network system suitable for use in implementing some embodiments of the present disclosure.

FIG. 1C illustrates a block diagram of a prior art optical-based network system.

FIG. 1D illustrates a conceptual diagram of an example ECS suitable for use in implementing some embodiments of the present disclosure.

FIG. 1E shows the use of ECS to enable a four-enclosure system with all electrical signaling suitable for use in implementing some embodiments of the present disclosure.

FIG. 2A shows a sliced ECS configuration suitable for use in implementing some embodiments of the present disclosure.

FIG. 2B shows the use of ECS to enable an eight-enclosure system with all electrical signaling suitable for use in implementing some embodiments of the present disclosure.

FIG. 2C illustrates a block diagram of an example switch-based processor group with ECS, in accordance with an embodiment.

FIG. 2D illustrates a prior art optical-based dragonfly network topology.

FIG. 3 illustrates a flowchart of a method for configuring ECSs within a rack system, in accordance with an embodiment.

FIG. 4 is a conceptual diagram of a processing system implemented using a PPU, suitable for use in implementing some embodiments of the present disclosure.

FIG. 5A illustrates an exemplary system in which the various architecture and/or functionality of the various previous embodiments may be implemented.

FIG. 5B illustrates components of an exemplary system that can be used to train and utilize machine learning, in at least one embodiment.

FIG. 6 illustrates an exemplary streaming system suitable for use in implementing some embodiments of the present disclosure.

### DETAILED DESCRIPTION

Systems and methods are disclosed related to an electrical circuit switch for cluster networks. In an embodiment, a cluster network is implemented using NV-link. Systems and methods are disclosed for electrically transmitting signals between different racks that each include at least one electrical circuit switch (ECS). In contrast to conventional systems, the ECS transmits signals over wires without requiring optical transceivers to convert between optical-based signaling (light) and electrical-based signaling (current). The ECS operates as a repeater, amplifying and routing the electrical signals to enable transmission over distances greater than one meter, enabling electrical signaling to be used to construct networked clusters of processors across multiple rack enclosures. Within an enclosure, ECSs are connected through circuit boards populated with multiple processors. The circuit boards within the enclosure are connected to each other via a backplane, a midplane, or electrical cables.

In an embodiment, the ECS includes a plurality of input ports and a plurality of output ports, where each input port may be coupled via a repeater and multiplexer to any one of the output ports, providing a dedicated point-to-point communication path or link. Configuration of the connections between input ports and output ports may be programmed to assign and reassign processors to clusters (partitions). The network maybe incrementally expanded without physically rewiring connections between existing rack enclosures. Spare processors within an enclosure may be configured to replace defective processors without physically rewiring connections.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

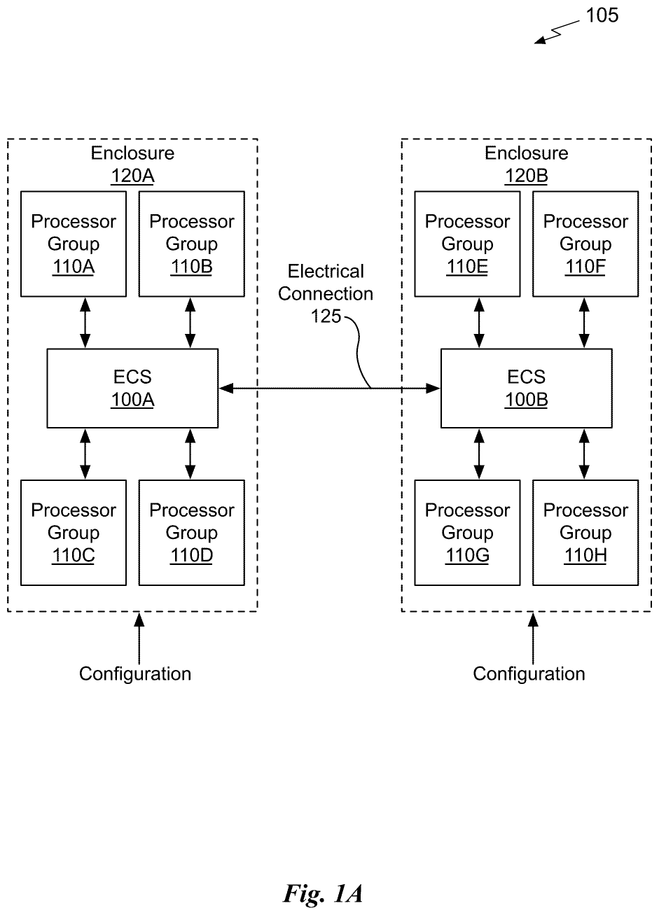

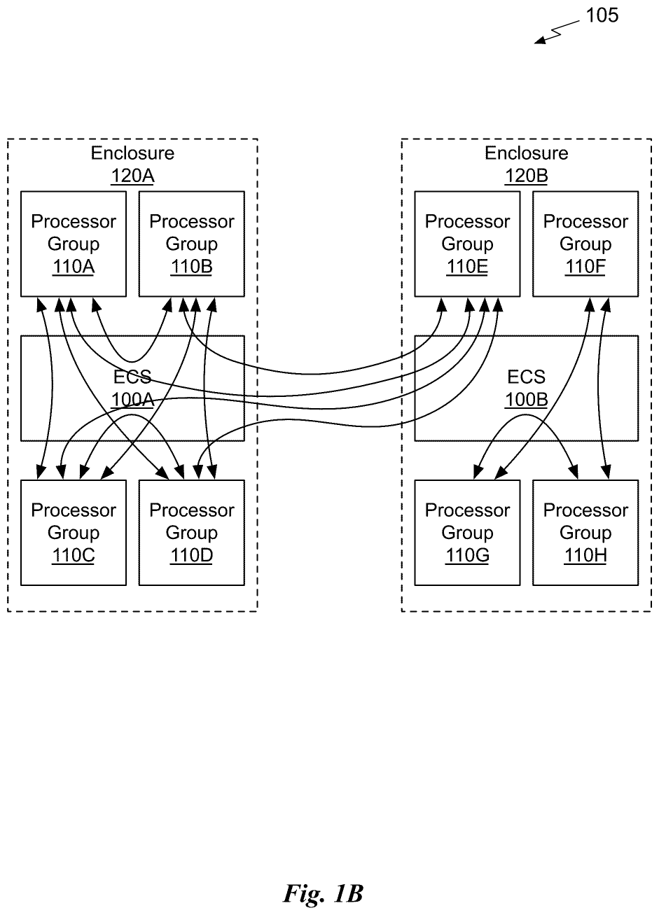

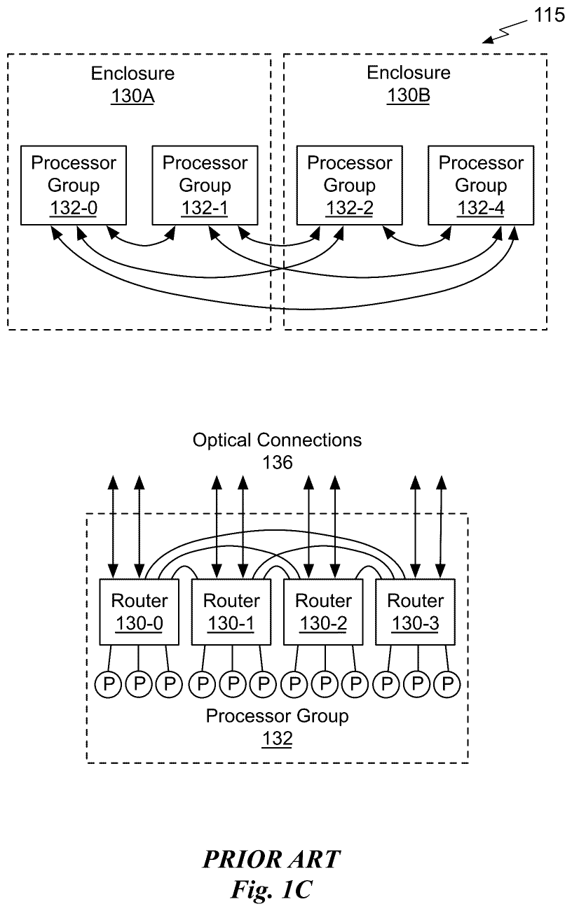

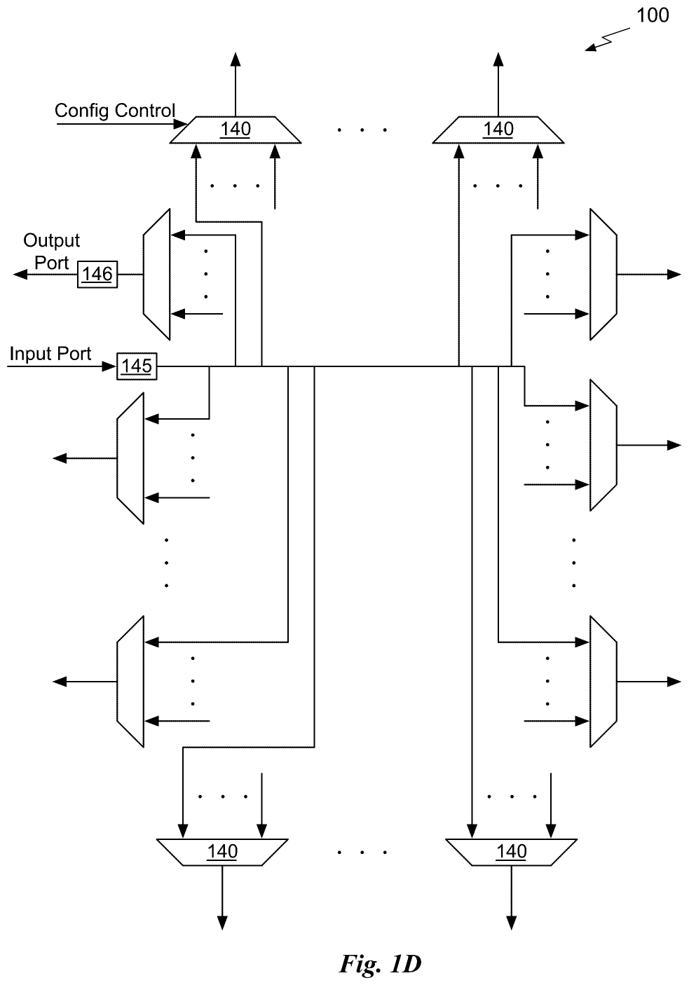

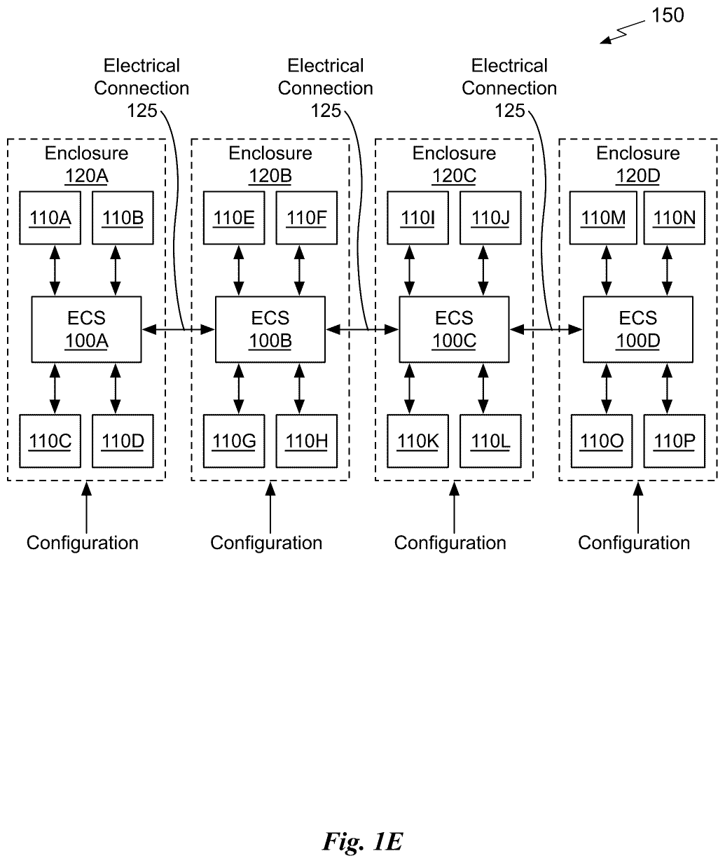

FIG. 1A illustrates a block diagram of an example ECS cluster network system 105 suitable for use in implementing some embodiments of the present disclosure. Each enclosure 120 includes multiple processors in processor groups 110 and at least one ECS 100. FIG. 1A illustrates two enclosures 120 and in other embodiments, the ECS cluster network system 105 may include more enclosures 100 or only a single enclosure 100. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. Furthermore, persons of ordinary skill in the art will understand that any system that performs the operations of the ECS cluster network system 105 is within the scope and spirit of embodiments of the present disclosure.

The ECS cluster network system 105 comprises an electrical connection 125 to provide transmission connections between the enclosure 120A and 120B. Connections between the processor groups 110 and ECS 100 within each of the enclosures 120 are also provided by electrical connections. For example, in an embodiment, each processor group 110 includes 36 processors (CPU, GPU, or the like) and each one of the processors is directly coupled to the ECS 100 through an electrical connection. The transmission connections may comprise conductive wires, twisted pair copper cables (e.g., ethernet), twinaxial cables, coaxial cables, and the like. In an embodiment, transmission signaling is differential and simultaneous bidirectional. In an embodiment, the signaling is single-ended and/or single-directional.

The processors may be organized into multiple processor groups 110 of a hierarchical dragonfly network topology, where the processors within each processor group 110 are directly coupled point-to-point with each other by local communication links (not shown). The local links (connections) are dedicated and independent of each other, providing intra-connectivity within each processor group 110 at a first hierarchical level. In an embodiment, the local links are routed through the ECS 100, enabling replacement of a non-functional processor with a spare processor in the same processor group 110.

A cluster or partition may be defined that includes at least one processor group 110. The ECSs 100 are configured to provide the intra group local communication links (local links) and inter group global communications links (global links), where all of the links within each enclosure 120A or 120B and between different enclosures, such as between the enclosures 120A and 120B over the electrical connection 125 use only electrical signaling. Furthermore, in an embodiment, the ECSs 100 are configured to provide the global links for one cluster without interfering with traffic over either local links or global links for a different cluster.

FIG. 1B illustrates another block diagram of an example ECS cluster network system 105 suitable for use in implementing some embodiments of the present disclosure. In an embodiment, processor groups 110A, 110B, 110C, 110D, and 110E are assigned to a first cluster and processor groups 110F, 110G, and 110H are assigned to a second cluster. The ECS 100A is configured to provide local links between each pair of processors within each one of the four processor groups 110A, 110B, 110C, and 110D. Similarly, the ECS 100B is configured to provide local links between each pair of processors within the processor group 110E, 110F, 110G, and 110H. The ECSs 100A and 100B are configured to provide global links between each pair of processor groups 110A, 110B, 110C, 110D, and 110E that are included in the first cluster. The global links for the first cluster are shown as bidirectional arrows between each pair of the processor groups 110 in the first cluster. Similarly, The ECSs 100A and 100B are configured to provide global links between each pair of processor groups 110F, 110G, and 110H that are included in the second cluster. The global links for the second cluster are shown as bidirectional arrows between each pair of the processor groups 110 in the second cluster. No links are provided between any of the processor groups 110A, 110B, 110C, 110D, and 110E that are assigned to the first cluster and the processor groups 110F, 110G, and 110H that are assigned to the second cluster. A portion of the global links for the first cluster include the electrical connection 125.

Each processor group 110 may include one or more spare processors and the ECS 100 may be configured to replace a failed processor with one of the spare processors within the same processor group 110, adding the local and global links to the spare processor and removing the local and global links to the failed processor.

FIG. 1C illustrates a block diagram of a prior art optical-based network system 115. In an embodiment, the optical-based network system 115 is manually configured in a Dragonfly topology. The Dragonfly topology is described in detail by Kim, John, et al. “Technology-Driven, Highly-Scalable Dragonfly Topology.” 2008 International Symposium on Computer Architecture. IEEE, 2008. The optical-based network system 115 includes two enclosure, enclosure 130A and 130B, where each of the enclosures 130 includes two processor groups 132. As shown below, each processor group 132 includes multiple processors (P) and routers 130-0, 130-1, 130-2, and 130-3. The routers 130 provide local connections between each pair of processors in the processor group 132 through electrical connections. While connections between processors groups 132-0 and 132-1 within the same enclosure 130A may be implemented as electrical connections, connections between enclosure 130A and 130B are implemented using the optical connections 136. Similarly, connections between processor groups 132-2 and 132-3 within the same enclosure 130B may be implemented as electrical connections, the connections between enclosure 130A and 130B are implemented using the optical connections 136.

Without the ECS 100, the optical-based network system 115 is configured manually, by physically coupling an optical-based cable between the enclosures 130A and 130B. Changing cluster assignments, such as adding processor group 132-4 to a cluster that includes processor groups 132-0, 132-1, and 132-2 requires physically adding an optical-based cables between the enclosures 130A and 130B and moving existing optical-based cables. An advantage of the Dragonfly topology is that each path between two processors passes through only one global link. However, compared with the ECS 100, a path through each router 130 (or a packet switch) additional latency due to the extraction of a packet header, decoding of the packet header, and routing of the packet. In contrast, the ECS 100 operates as a “patch panel”, simply providing an electrical connection between an input port and an output port through a deserializer, a multiplexer, and a serializer without performing any extraction or decoding operations.

FIG. 1D illustrates a conceptual diagram of an example ECS 100 suitable for use in implementing some embodiments of the present disclosure. The ECS 100 includes multiple input ports, multiple output ports, and an interface for programming a configuration (config control) that is stored in a register (not shown). Each one of the input ports may be coupled to any one of the output ports via multiplexers 140. FIG. 1D illustrates one connection between an input port that is coupled to an output port by a multiplexer 140 controlled by config control. In an embodiment, a deserializer 145 is coupled to each input port and a serializer 146 is coupled on each output port. In an embodiment, a 200 Gb/s input is deserialized to a 128 b wide signal at 1.56 GHz. The wide, slow signal is switched by the multiplexer 140 and then serialized to 200 Gb/s at the output port. In an embodiment, the deserializer 145 includes a repeater or circuitry that performs the function of a repeater, amplifying and reclocking at least one of the input or the deserialized input. In an embodiment, the serializer 146 includes a repeater or circuitry that performs the function of a repeater, amplifying and reclocking at least one of the output from the multiplexer 140 or the serialized output to the output port. The input ports and output ports are each coupled to an external pin and pad of an integrated circuit die within which circuitry for the ECS 100 is fabricated. Additional deserializers 145 and serializers 146 for each of the input ports and output ports, respectively, are omitted for clarity.

In addition to providing a conductive path, the repeater connects each external pin to inputs of the multiplexers 140 amplifying the transmitted signals between the ECSs 100 in different racks or enclosures. Any one of the input ports may be selected by the multiplexer 140 for connection to an output port using the config control. In an embodiment, one of the input ports is selected for connection to multiple output ports. The ECS 100 enables construction of dragonfly network topologies for clusters of processor groups, providing dedicated point-to-point paths (links or connections) where each path is dedicated to a single cluster. Transmissions through links or channels shared by two or more clusters are not possible. In other words, the multiplexers do not dynamically select between the different input ports based on any decoding of a header or other routing information included in a packet received at an input port. In an embodiment, each local link passes through the ECS 100 and may be configured by programming the config control registers. In an embodiment, the local links for each processor group 110 are “hardwired” within each processor group 110 and cannot be configured, as the local links do not pass through the ECS 100.

Once the ECS cluster network system 105 is configured for a particular processing task, the processing groups 110 are assigned to clusters and the config control is unchanged until the processing task is completed and one or more of the processing groups 110 are reassigned for processing another task. Furthermore, the use of ECSs 100 allows expansion and/or reconfiguration of a dragonfly network topology without physical rewiring between enclosures 120 or within an enclosure 120. Similarly, a spare processor may be swapped in to replace a defective processor without physical rewiring. Furthermore, an additional enclosure 120 may be added or an enclosure 120 may be removed and the ECSes 100 can reconfigure the links as needed once the cables between enclosures are attached or removed.

As previously described, when clusters are configured, the processor groups 110 within a single cluster communicate with each other, but do not communicate with processor groups 110 outside of the cluster. Therefore, the unused global links between processor groups 110 in different clusters may be configured as global links between the different processor groups 110 within the same cluster, providing additional bandwidth within the cluster. When a cluster frees up, the processor groups 110 allocated for the cluster may be configured as two or more clusters or combined with other processor groups 110 to form a new cluster. Transmissions that pass through a first ESC 100 in an enclosure 120 to reach a second ESC 100 in another enclosure 120 do not interfere with other transmissions occurring in the first ESC 100 because each global link is separate and independent. Thus, bandwidth provided by each global or local link is dedicated for the processors within the same cluster or within the same processor group 110, respectively.

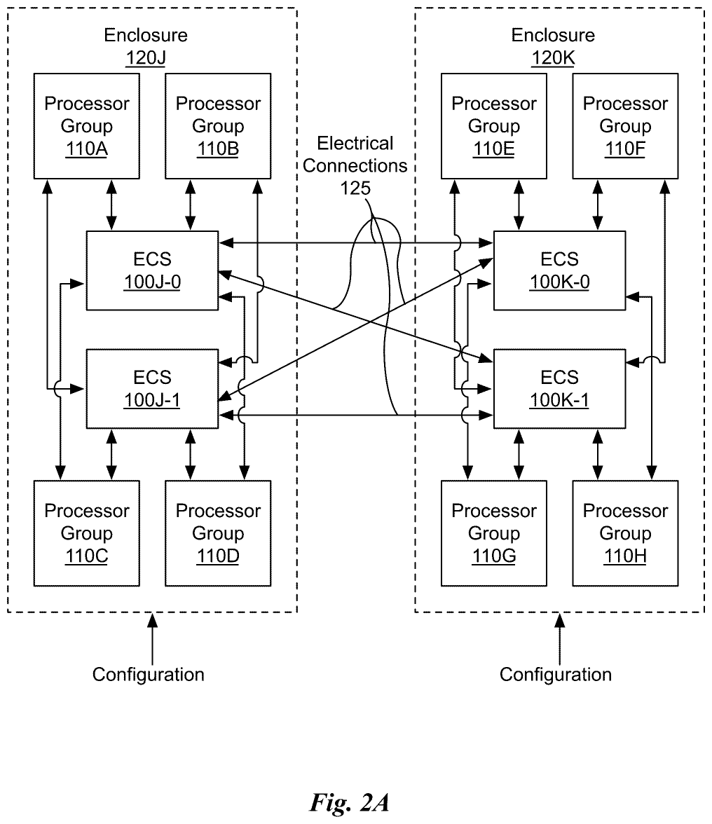

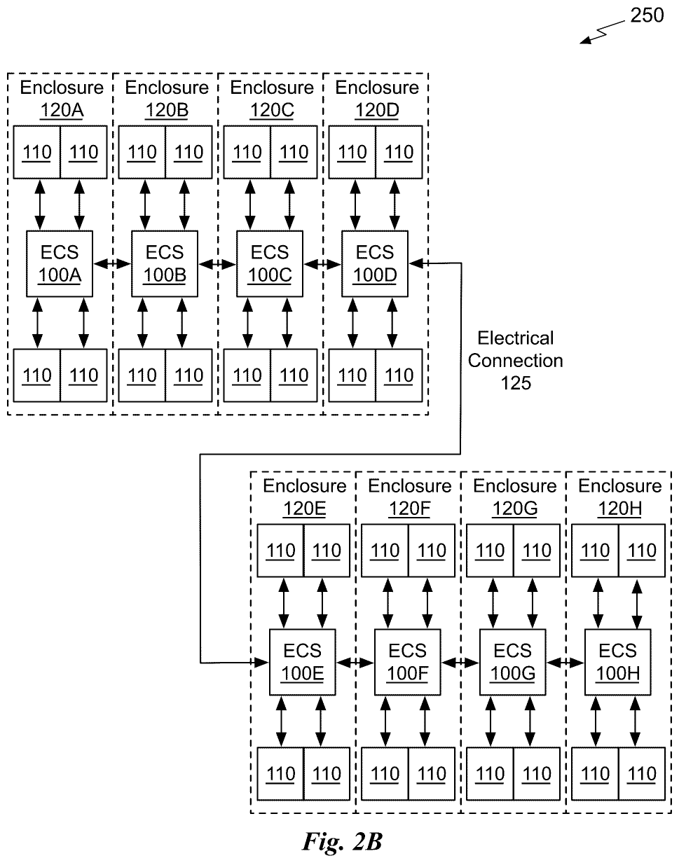

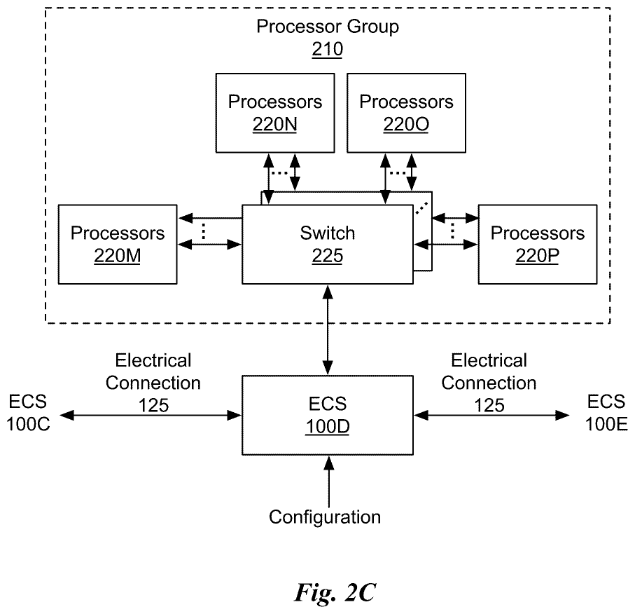

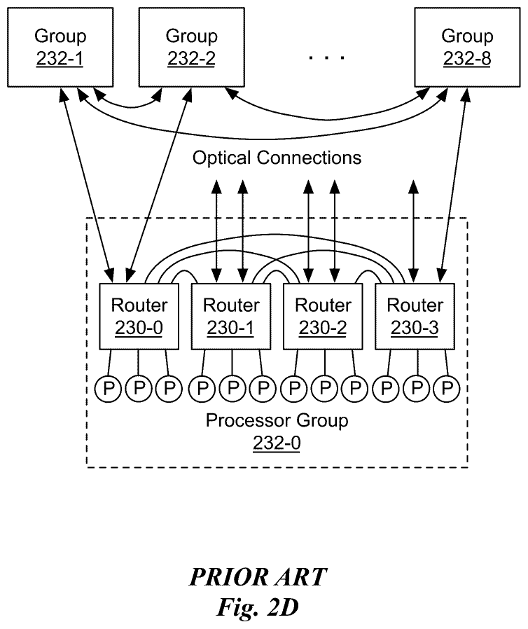

FIG. 1E shows the use of ECS to enable a four-enclosure system 150 with all electrical signaling. Compared with the ECS cluster network system 105 shown in FIG. 1A, the four-rack system 150 includes two additional enclosures 120C and 120D. In one embodiment, each enclosure 120 contains 72 GPUs. Each processing group 110 denotes 18 GPUs. The four-enclosure system 150 contains 288 GPUs. In one embodiment each GPU is directly connected to an ECS 100. In an alternate embodiment, shown in FIG. 2C, each processing group 110 also includes a switch and each GPU is connected to the ECS 100 via the switch.

In one embodiment, each GPU has 36 NV-link channels, so that each vertical arrow between a processing group 110 and an ECS 100 represents 648 bi-directional NV-Link channels, all of the channels from each of the 18 GPUs in each processing group 110. The electrical connections 125 represent sufficient channels to connect the entire four-enclosure system 150 in a dragonfly network topology.

For example, a dragonfly network topology may be configured across the four enclosures 120A, 120B, 120C, and 120D with 16 processing groups 110 of 16 GPUs each (a total of 256 GPUs). The four processing groups 110 in each enclosure 120 include 64 GPUs. The remaining eight GPUs in each enclosure 120 (two in each processing group 110) are spares—but can still be used while acting as a spare. 30 of the 36 links on each GPU are local links (intra-group)—two to each one of the neighboring GPUs in the processing group 110. To provide the same taper as a conventional system, two global links per processing group 110 are provisioned to each of the other 15 processing groups 110. Thus, there are a total of 15×2=30 global links out of each processing group 110 or 30/16=1.875 global links per GPU. The provisioning requires 1.875 links per GPU. Therefore, in an embodiment, 14 of the GPUs in the processing group 110 each have two global links and the remaining 2 GPUs in the processing group 110 each have one global link.

Within each enclosure 120, each processing group 110 has six global links to the other processing groups 110 in the same enclosure 120—2 global links each to 3 other processing groups 110. The remaining 24 global links exit the enclosure 120 through the electrical connection 125. Each of the end enclosures 120A and 120D exports 96 global links—24 global links from each of the 4 processing groups 110 in the enclosures 120A and 120D. The electrical connection 125 between enclosures 120A and 120B (and between enclosures 120C and 120D) carries 96 global links. The electrical connection 125 between enclosures 120B and 120C carries 32 global links—16 from enclosure 120A forwarded through the ECS 100 in enclosure 120B, and 16 from the enclosure 120B.

FIG. 2A shows a sliced ECS configuration suitable for use in implementing some embodiments of the present disclosure. In an embodiment, each enclosure 120J and 120K includes multiple ECSs 100. As shown in FIG. 2A, two ECSes 100 are included in each enclosure 120 and, within each enclosure 120, each ECS 100 is coupled to all of the processor groups 110. For example, the processor groups 110A, 110B, 110C, and 110D are each coupled to ECS 100J-0 and 100J-1 within the enclosure 120J. Similarly, the processor groups 110E, 110F, 110G, and 110H are each coupled to ECS 100K-0 and 100K-1 within the enclosure 120K. The processor groups 110 are “sliced” across the ECSes 100 within each enclosure 120 and the ECSes 100 are “sliced” across the enclosures 120. For example, the ECS 100J-0 is coupled to the processor groups 110A and 110B and the ECS 100J-1 is coupled to the processor groups 110C and 110D. Similarly, the ECS 100K-0 is coupled to the processor groups 110E and 110F and the ECS 100k-1 is coupled to the processor groups 110G and 110H. Each slice comprises a portion of the processors in the processor groups 110, local connections between the portion of processors, and global connections through the associated slice of the ECSes 100.

A portion of each of the processor groups 110A, 110B, 110C, 110D, 110E, 110F, 110G, and 110H is included in a first slice and a remaining portion of each of the processor groups 110A, 110B, 110C, 110D, 110E, 110F, 110G, and 110H is included in a second slice. Each ECS 100 is also sliced into a first and second slice. The ECSes 100J-0, 100J-1, 100K-0, and 100K-1 may be configured to provide first local dedicated and independent communication paths between each processor in the first slice and second local dedicated and independent communication paths between each processor in the second slice. Slicing the processor groups 110 across the ECSes 100 distributes traffic across the ECSes 100 and distributes the processing workload across the processor groups 110.

To maximize the “wireability” of the sliced ECS 100J-0, the per-slice connections of the electrical connections 125 provided by the ECS 100J-0 should be interleaved across the slices of the ECS 100K-0 and ECS 100K-1 in the adjacent enclosure 120K—with 10 connections to each slice. Similarly, the per-slice connections of the electrical connections 125 provided by the ECS 100J-1 should be interleaved across the slices of the ECS 100K-0 and ECS 100-K1 in the adjacent enclosure 120K. Therefore, the ECS 100J-0 is also directly coupled to the ECS 100K-1 and the ECS 100J-1 is also directly coupled to the ECS 100K-1.

In an embodiment, multiple ECSes 100 within a single enclosure, such as the ECS 100J-0 and ECS 100J-1 are directly coupled to each other using electrical connections instead of optical connections. In such an embodiment, each ECS 100 within the same enclosure 120 may be coupled to only a portion of the processor groups 110 within the same enclosure 120. For example, the ECS 100J-0 is coupled to the processor groups 110A and 110B, but not to the processor groups 100C and 110D. In an embodiment, the ECSs 100J-0 and 100J-1 are sliced when coupled to at least one ECS 100 in a different enclosure 120.

FIG. 2B shows the use of ECS 100 to enable an eight-enclosure system 250 with all electrical signaling suitable for use in implementing some embodiments of the present disclosure. Compared with the ECS cluster network system 150 shown in FIG. 1D, the eight-rack system 250 includes four additional enclosures 120E, 120F, 120G, and 120H. A dragonfly network topology may be configured across the eight enclosures with 32 processing groups 110 of 16 GPUs each (a total of 512 GPUs). Each processing group 110 includes 16 GPUs and 2 spares, for a total of 64 GPUs in each enclosure 120. As in the previous four enclosure example, 30 of the 36 links on each GPU are local links (intra-group)—two to each of one of the neighboring GPUs in the processing group 110. To provide the same taper as a conventional system, two links per processing group 110 are provisioned to each of the other 31 processing groups 110 in the eight-enclosure system 250. Thus, there are a total of 31×2=62 global links out of each processing group 110 and 56 global links exit each enclosure 120. The provisioning requires 62/16=3.875 global links per GPU. Therefore, 14 of the GPUs in the processing group 110 have 4 global links and the remaining 2 GPUs in the processing group 110 have 3 global links.

Each of the end enclosures 120A and 120H exports 224 global links (56 from each of the 4 processing groups 110). The electrical connection 125 between enclosures 120A and 120B carries 224 global links. The electrical connection 125 between enclosures 120B and 120C carries 96 global links—48 from enclosure 120A forwarded through the ECS 100 in enclosure 120B, and 48 from the enclosure 120B. Similarly, the electrical connection 125 between enclosures 120F and 120G carries 96 global links—48 from enclosure 120H forwarded through the ECS 100 in enclosure 120G, and 48 from the enclosure 120G. The electrical connection 125 between enclosures 120C and 120D carries 120 global links—40 from each of the enclosures 120A, 120B, and 120C. Similarly, the electrical connection 125 between enclosures 120E and 120F carries 120 global links—40 from each of the enclosures 120H, 120G, and 120F. Finally, the electrical connection 125 between enclosure 120D and 120E carries the bisection of the network, 128 global links—32 from each of the first four enclosures 120A, 120B, 120C, and 120D or 32 from each of the second four enclosures 120E, 120F, 120G, and 120H.

The eight-enclosure system 250 (512 GPUs plus 64 spares) may be provisioned to have two 256 GPU dragonfly clusters, 16 processor groups 110 of 16 GPUs each in a first and second cluster. Without an ECS 100, a conventional eight-enclosure system is wired with each processor group having 2 global links to each of the other 31 processor groups in the eight enclosures. Thus, for non-minimal traffic, some amount of traffic from the first cluster routes through a second cluster, causing interference in the conventional eight-enclosure system. In contrast, with the ECS 100, the 8-rack system can be dynamically rewired by changing the configuration control so that each processor group 110 has 4 global links to each of the 15 other processor groups 110 within the same cluster. No traffic within the first cluster is routed through the second cluster, thereby eliminating cross-cluster interference.

In an embodiment, each cluster is defined and configured for execution of a particular task and when execution of the task is complete, the processing groups 110 included in the cluster may be reconfigured for execution of a new task. For example, a first cluster may be defined that includes all processor groups 110 in the enclosure 120A and a subset of (one, two, or three) of the processor groups 110 in the enclosure 120B. The configuration control provided to the ECSs 110A and 110B within enclosures 120A and 120B, respectively, may implement global links to each processor group 110 in the first cluster. The global links provide dedicated and independent communication paths between each one of the processors in the first cluster and other processors in the first cluster. Importantly, traffic within other clusters will not be transmitted over the global links within the first cluster. The global and local links within the first cluster transmit signals as an electrical current from a first processor in a first processor group 110 within the enclosure 120A, through the electrical connection 125 between the ECS 100A and the ECS 100B to a second processor in the subset of the processor groups 110 in the enclosure 120B. Configuration of the global links provide dedicated and independent communication paths for the first cluster that are isolated from other clusters. In an embodiment, the signals are not transmitted between the enclosures 120 using optical technology.

In an embodiment, after completion of a processing task, the first cluster may be reconfigured to remove or add processing groups 110 into the cluster, defining a second cluster. For example, at least one additional processing group 110 in the enclosure 120E may be added to the first cluster to produce the second cluster. The configuration control for the ECS 100A, 100B, and 100D may be updated to provide global links between each pair of processing groups 110 in the second cluster. In contrast with conventional systems without the ECS 100, cables need not be manually changed as the clusters are modified. The configuration control may be changed using a program instruction, as tasks are executed. Modification of the configuration control may be initiated remotely or locally. Furthermore, global links with ECSs 100 in one or more enclosures 120 may be added or removed by updating the configuration control as enclosures 120 are added or removed.

The ECS 100 can also be used to swap in one of the spare GPUs to replace a failed GPU within the same enclosure 120. When all of the 36 local and global links (e.g., NVLink channels) exiting a GPU are routed through the ECS 100, it is straightforward to disconnect a failed GPU and to have the links for a spare GPU replace the connections. For example, the configuration control may be changed to remove the local and global links for the failed processor and connect the local and global links to the spare processor.

The amount of ECS 100 bandwidth needed can be greatly reduced by using the ECS 100 only for global (inter-group) connections. In such a system, the 16 processors in each processor group 110 (possibly with attached switches) are directly connected—along with a spare processor—to make 17 processors per processor group 110. The ECS 100 then handles only the inter-group links, four per processor, in an embodiment. Thus, in a 72 processor rack the ECS 100 needs to handle only 144 global up links, 144 global down links (or 288 bidirectional global links), and up to 128 global links exiting the enclosure 120 for a total of up to 544 links. In an embodiment, the ECS 100 is implemented as a single radix 588 electrical circuit switch.

In an embodiment, the ECS 100 within an enclosure 120 is implemented as two or more ECS 100 devices to provide a greater number of connections (global only or global and local). When multiple ECS 100 devices are implemented within the same enclosure 120, the ECS 100 may be “sliced” into subsets of connections and slices of the ECS 100 may be interleaved to maximize wireability.

FIG. 2C illustrates a block diagram of an example switch-based processor group 210 with ECS 100D, in accordance with an embodiment. In the eight-enclosure system 250 example, the ECS 100D in enclosure 120D has a total of 2,840 connections—1,296 between the ECS 100D and processing groups 110M and 110N, 1,296 between the ECS 100D and processing groups 110O and 110P, 120 global links through the electrical connection 125 with the enclosure 120C, and 128 global links through an electrical connection 125 with the enclosure 110E. As shown in FIG. 2C, the ECS 100D has a radix of 512 200 Gb/s channels. In an embodiment, at least one switch 225 is included in the processor group 210. In an embodiment, the switch 225 is a packet switch. In an embodiment, the local connections are not routed through the switch 225 and are routed directly between the processors 220 in the processor group 210. The per-enclosure ECS 100 may be implemented by dividing the connections across six switches 225. Each switch 225 has 216 connections to processing groups 110M and 110N, 216 connections to processing groups 110O and 110P, 20 connections through the electrical connection 125 with the enclosure 120C, and 21 or 22 connections through an electrical connection 125 with the ECS 100E in the enclosure 120E.

In a conventional dragonfly network topology, it is sometimes necessary to route through a cluster to communicate with a different processor group in the same cluster and such “through” transmissions occupy pin bandwidth of the processor. Use of the switch 225 avoids the need to route through any of the processors and thereby avoids consuming pin bandwidth for through communications (i.e., communications for which the processor is neither a destination or source).

FIG. 2D illustrates a prior art optical-based dragonfly network topology. The prior art optical-based dragonfly network topology includes nine processor groups 232-0 through 232-8 and each processor group includes four routers 230, as shown in detail of the processor group 232-0. Each of the routers 230 is connected to three processors. In an embodiment, the prior art optical-based dragonfly network topology is configured into a first cluster including processor groups 232-0 and 232-1. A second cluster includes processor group 232-2 and processor group 232-8. The processor group 232-8 may transmit a message through the processor group 232-0 to reach the processor group 232-2 when the shorter path between processor group 232-8 and 232-2 is congested, interfering with communications within the first cluster by passing through the router 230-3 and 230-0. In contrast, because the ECS 100 provides separate point-to-point global links, including for paths that pass through an ECS 100, communications within a first cluster do not interfere with communications within a second cluster. Furthermore, the ECS 100 allows expansion of a dragonfly network topology without physical rewiring of the optical connections between enclosures and/or electrical connections between different groups within the same enclosure. Finally, the ECS 100 also allows a spare processor within a processor group to be configured into the dragonfly network topology without modifying the physical electrical connections. Instead, the configuration register may be updated to add point-to-point connections to the spare processor.

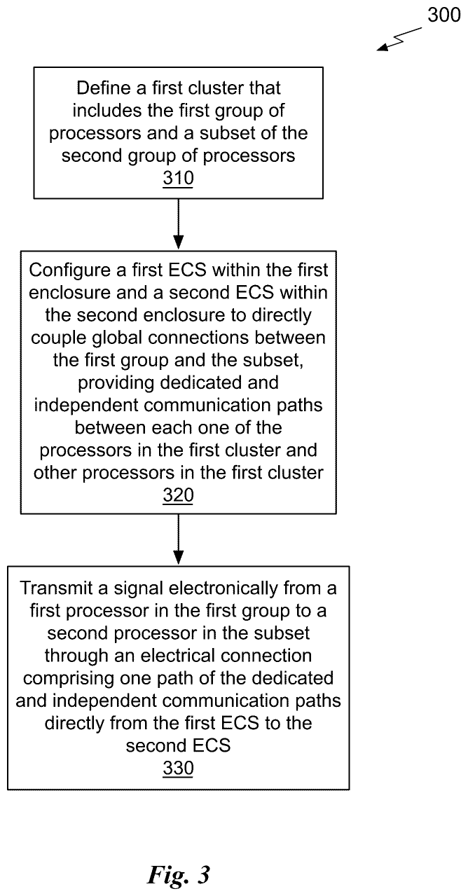

FIG. 3 illustrates a flowchart of a method 300 for configuring electrical circuit switches within a rack system including at least a first group of processors within a first enclosure and a second group of processors within a second enclosure, the first group and the second group each including at least one processor, in accordance with an embodiment. Each block of method 300, described herein, comprises a computing process that may be performed using any combination of hardware, firmware, and/or software. For instance, various functions may be carried out by a processor executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 300 is described, by way of example, with respect to the system of FIGS. 1A, 1D, and 1E. However, this method may additionally or alternatively be executed by any one system, or any combination of systems, including, but not limited to, those described herein. Furthermore, persons of ordinary skill in the art will understand that any system that performs method 300 is within the scope and spirit of embodiments of the present disclosure.

At step 310, a first cluster is defined that includes the first group of processors and a subset of the second group of processors. At step 320, a first electrical circuit switch (ECS) within the first enclosure and a second ECS within the second enclosure are configured to directly couple global connections between the first group and the subset, providing dedicated and independent communication paths between each one of the processors in the first cluster and other processors in the first cluster. In an embodiment, the first ECS is configured to provide local dedicated and independent communication paths between each processor within the first group and every other processor within the first group.

In an embodiment, at least a first portion of the processors within the first group is associated with a first packet switch and the first ECS is configured to provide local dedicated and independent communication paths between each processor in the first portion and a second packet switch associated with a second portion of the processors within the first group.

In an embodiment, a first processor within the first group is a spare processor. In an embodiment, a second processor in the first group is determined to have failed and the first ECS is configured to replace a first global connection of the global connections between the second processor and the subset with second global connection of the global connections between the first processor and the subset.

At step 330, a signal is transmitted electronically from a first processor in the first group to a second processor in the subset through an electrical connection comprising one path of the dedicated and independent communication paths directly from the first ECS to the second ECS. In an embodiment, the signal is transmitted only as an electrical current through the one path.

In an embodiment, a third group of processors within a third enclosure is added to the first cluster by configuring the first ECS, the second ECS, and a third ECS within the third enclosure to provide additional global connections between the third group and the subset and between the third group and the first group to form a second cluster. In an embodiment, the additional global connections are coupled through the first ECS to the second ECS. In an embodiment, the first ECS and the second ECS are configured to provide additional global connections with at least one group of processors in the second group of processors that is not included in the subset. In an embodiment, the first ECS and the second ECS are configured to provide additional global connections with at least one group of processors in the second group of processors that is not included in the subset.

In an embodiment, the first group is removed from the first cluster to form a second cluster that includes the subset and a third group of processors within a third enclosure by configuring the first ECS, the second ECS, and a third ECS within the third enclosure to provide additional global connections with the third group and the subset and remove (disconnect or decoupled) a portion of the global connections between the first group and the subset.

In an embodiment, local dedicated and independent communication paths between each processor within the first group and every other processor within the first group are hardwired without passing through the first ECS. In an embodiment, the first ECS is configured to provided additional dedicated and independent communication paths between processors in a second cluster that are separate from and support transmissions that occur simultaneously with transmissions on the dedicated and independent communication paths for the first cluster.

Embodiments of the present disclosure relate to an electrical circuit switch for wire-based networks, such as NV-link. Systems and methods are disclosed for electrically transmitting signals between different racks that each include at least one electrical circuit switch (ECS). In contrast to conventional systems, the ECS 100 transmits signals over wires without requiring optical transceivers to convert between optical-based signaling (light) and electrical-based signaling (current). Compared with optical-based signaling, using electrical-based signaling provides an order of magnitude reduction in system cost. The ECS 100 also allows the configuration of dragonfly network topologies in a manner that avoids running non-minimal traffic between processors in one cluster through paths within other clusters. The ECS 100 operates as a repeater, amplifying and routing the electrical signals to enable transmission over distances greater than a meter, enabling electrical signaling to be used to construct networked clusters of processors across multiple rack enclosures. In an embodiment, the ECS 100 includes a plurality of input ports and a plurality of output ports, where each input port may be coupled via a repeater and multiplexer to any one of the output ports, providing a dedicated point-to-point communication path or link. Configuration of the connections between input ports and output ports may be programmed. The network may be incrementally expanded without physically rewiring connections between existing rack enclosures. Spare processors within an enclosure may be configured to replace defective processors without physically rewiring connections.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

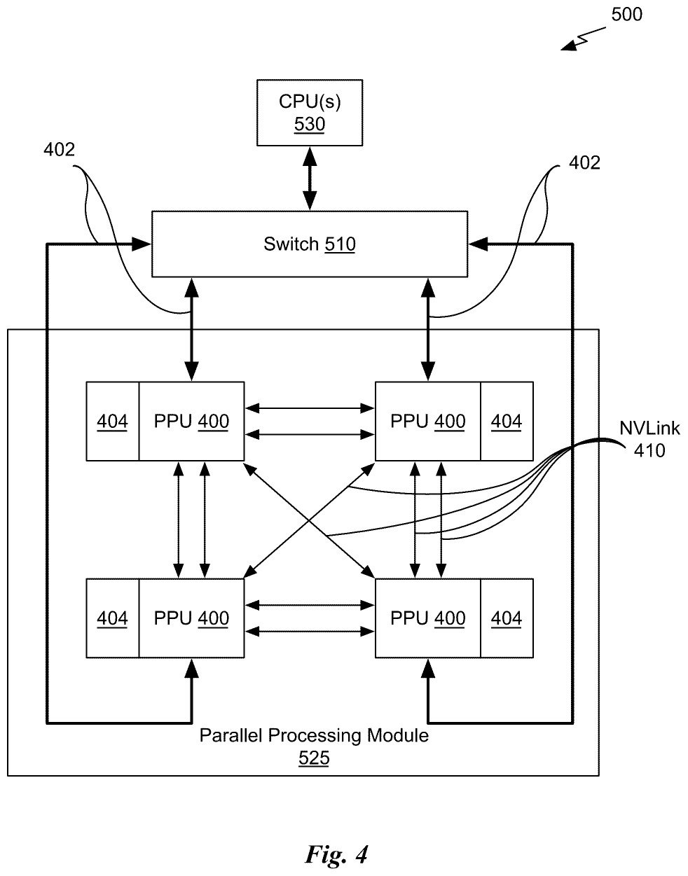

FIG. 4 is a conceptual diagram of a processing system 500 implemented using the PPU 400 of FIG. 4, in accordance with an embodiment. The exemplary system 500 may be configured to implement the method 300 shown in FIG. 3. The processing system 500 includes a CPU 530, switch 510, and multiple PPUs 400, and respective memories 404.

Each parallel processing unit (PPU) 400 may include hundreds or thousands of cores that are capable of handling hundreds or thousands of software threads simultaneously. The PPUs 400 may generate pixel data for output images in response to rendering commands (e.g., rendering commands from the CPU(s) 530 received via a host interface). The PPUs 400 may include graphics memory, such as display memory, for storing pixel data or any other suitable data, such as GPGPU data. The display memory may be included as part of the memory 404. The PPUs 400 may include two or more GPUs operating in parallel (e.g., via a link). The link may directly connect the GPUs (e.g., using NVLINK 410) or may connect the GPUs through a switch (e.g., using switch 510). When combined together, each PPU 400 may generate pixel data or GPGPU data for different portions of an output or for different outputs (e.g., a first PPU for a first image and a second PPU for a second image). Each PPU 400 may include its own memory 404, or may share memory with other PPUs 400.

The PPUs 400 may each include, and/or be configured to perform functions of, one or more processing cores and/or components thereof, such as Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The NVLink 410 provides high-speed communication links between each of the PPUs 400. Although a particular number of NVLink 410 and interconnect 402 connections are illustrated in FIG. 4, the number of connections to each PPU 400 and the CPU 530 may vary. The switch 510 interfaces between the interconnect 402 and the CPU 530. The PPUs 400, memories 404, and NVLinks 410 may be situated on a single semiconductor platform to form a parallel processing module 525. In an embodiment, the switch 510 supports two or more protocols to interface between various different connections and/or links.

In another embodiment (not shown), the NVLink 410 provides one or more high-speed communication links between each of the PPUs 400 and the CPU 530 and the switch 510 interfaces between the interconnect 402 and each of the PPUs 400. The PPUs 400, memories 404, and interconnect 402 may be situated on a single semiconductor platform to form a parallel processing module 525. In yet another embodiment (not shown), the interconnect 402 provides one or more communication links between each of the PPUs 400 and the CPU 530 and the switch 510 interfaces between each of the PPUs 400 using the NVLink 410 to provide one or more high-speed communication links between the PPUs 400. In another embodiment (not shown), the NVLink 410 provides one or more high-speed communication links between the PPUs 400 and the CPU 530 through the switch 510. In yet another embodiment (not shown), the interconnect 402 provides one or more communication links between each of the PPUs 400 directly. One or more of the NVLink 410 high-speed communication links may be implemented as a physical NVLink interconnect or either an on-chip or on-die interconnect using the same protocol as the NVLink 410.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 525 may be implemented as a circuit board substrate and each of the PPUs 400 and/or memories 404 may be packaged devices. In an embodiment, the CPU 530, switch 510, and the parallel processing module 525 are situated on a single semiconductor platform.

In an embodiment, the signaling rate of each NVLink 410 is 20 to 25 Gigabits/second and each PPU 400 includes six NVLink 410 interfaces (as shown in FIG. 4, five NVLink 410 interfaces are included for each PPU 400). Each NVLink 410 provides a data transfer rate of 25 Gigabytes/second in each direction, with six links providing 400 Gigabytes/second. The NVLinks 410 can be used exclusively for PPU-to-PPU communication as shown in FIG. 4, or some combination of PPU-to-PPU and PPU-to-CPU, when the CPU 530 also includes one or more NVLink 410 interfaces.

In an embodiment, the NVLink 410 allows direct load/store/atomic access from the CPU 530 to each PPU's 400 memory 404. In an embodiment, the NVLink 410 supports coherency operations, allowing data read from the memories 404 to be stored in the cache hierarchy of the CPU 530, reducing cache access latency for the CPU 530. In an embodiment, the NVLink 410 includes support for Address Translation Services (ATS), allowing the PPU 400 to directly access page tables within the CPU 530. One or more of the NVLinks 410 may also be configured to operate in a low-power mode.

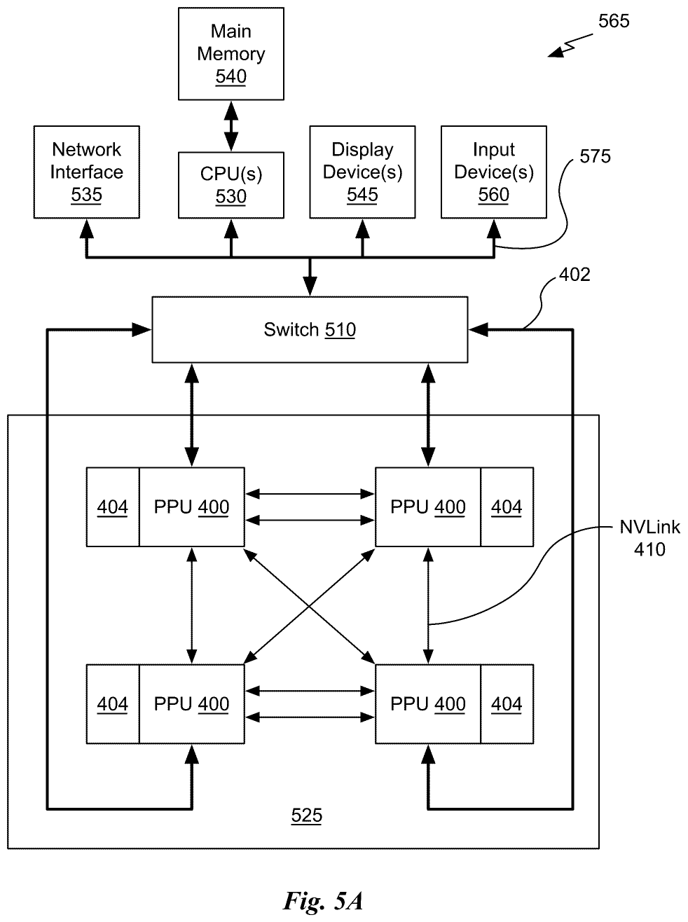

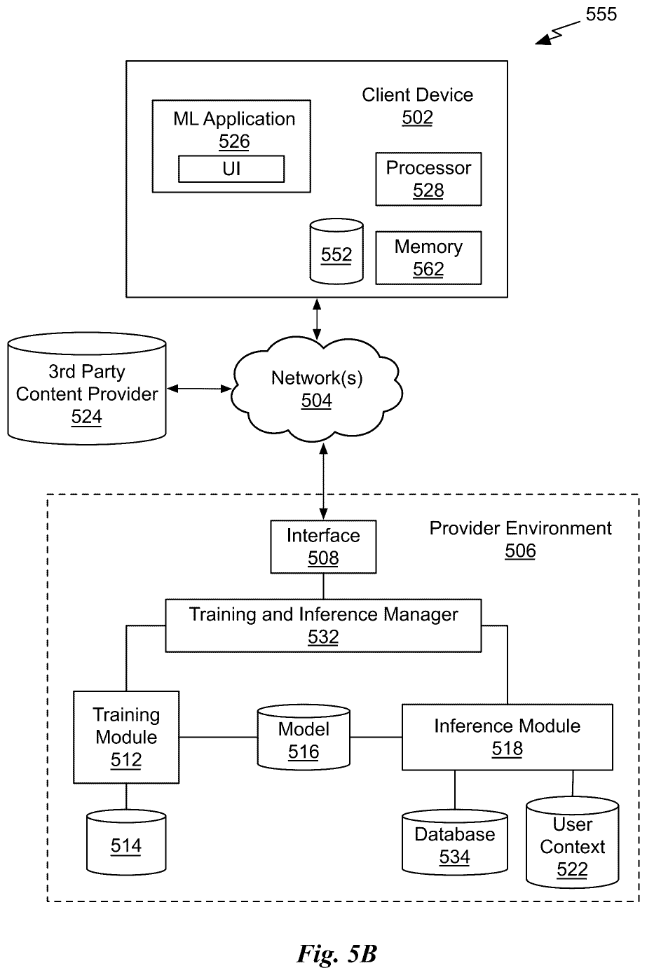

FIG. 5A illustrates an exemplary system 565 in which the various architecture and/or functionality of the various previous embodiments may be implemented. The exemplary system 565 may be configured to implement the method 300 shown in FIG. 3.

As shown, a system 565 is provided including at least one central processing unit 530 that is connected to a communication bus 575. The communication bus 575 may directly or indirectly couple one or more of the following devices: main memory 540, network interface 535, CPU(s) 530, display device(s) 545, input device(s) 560, switch 510, and parallel processing system 525. The communication bus 575 may be implemented using any suitable protocol and may represent one or more links or busses, such as an address bus, a data bus, a control bus, or a combination thereof. The communication bus 575 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, HyperTransport, and/or another type of bus or link. In some embodiments, there are direct connections between components. As an example, the CPU(s) 530 may be directly connected to the main memory 540. Further, the CPU(s) 530 may be directly connected to the parallel processing system 525. Where there is direct, or point-to-point connection between components, the communication bus 575 may include a PCIe link to carry out the connection. In these examples, a PCI bus need not be included in the system 565.

Although the various blocks of FIG. 5A are shown as connected via the communication bus 575 with lines, this is not intended to be limiting and is for clarity only. For example, in some embodiments, a presentation component, such as display device(s) 545, may be considered an I/O component, such as input device(s) 560 (e.g., if the display is a touch screen). As another example, the CPU(s) 530 and/or parallel processing system 525 may include memory (e.g., the main memory 540 may be representative of a storage device in addition to the parallel processing system 525, the CPUs 530, and/or other components). In other words, the computing device of FIG. 5A is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 5A.

The system 565 also includes a main memory 540. Control logic (software) and data are stored in the main memory 540 which may take the form of a variety of computer-readable media. The computer-readable media may be any available media that may be accessed by the system 565. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the main memory 540 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by system 565. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

Computer programs, when executed, enable the system 565 to perform various functions. The CPU(s) 530 may be configured to execute at least some of the computer-readable instructions to control one or more components of the system 565 to perform one or more of the methods and/or processes described herein. The CPU(s) 530 may each include one or more cores (e.g., one, two, four, eight, twenty-eight, seventy-two, etc.) that are capable of handling a multitude of software threads simultaneously. The CPU(s) 530 may include any type of processor, and may include different types of processors depending on the type of system 565 implemented (e.g., processors with fewer cores for mobile devices and processors with more cores for servers). For example, depending on the type of system 565, the processor may be an Advanced RISC Machines (ARM) processor implemented using Reduced Instruction Set Computing (RISC) or an x86 processor implemented using Complex Instruction Set Computing (CISC). The system 565 may include one or more CPUs 530 in addition to one or more microprocessors or supplementary co-processors, such as math co-processors.

In addition to or alternatively from the CPU(s) 530, the parallel processing module 525 may be configured to execute at least some of the computer-readable instructions to control one or more components of the system 565 to perform one or more of the methods and/or processes described herein. The parallel processing module 525 may be used by the system 565 to render graphics (e.g., 3D graphics) or perform general purpose computations. For example, the parallel processing module 525 may be used for General-Purpose computing on GPUs (GPGPU). In embodiments, the CPU(s) 530 and/or the parallel processing module 525 may discretely or jointly perform any combination of the methods, processes and/or portions thereof.

The system 565 also includes input device(s) 560, the parallel processing system 525, and display device(s) 545. The display device(s) 545 may include a display (e.g., a monitor, a touch screen, a television screen, a heads-up-display (HUD), other display types, or a combination thereof), speakers, and/or other presentation components. The display device(s) 545 may receive data from other components (e.g., the parallel processing system 525, the CPU(s) 530, etc.), and output the data (e.g., as an image, video, sound, etc.).

The network interface 535 may enable the system 565 to be logically coupled to other devices including the input devices 560, the display device(s) 545, and/or other components, some of which may be built in to (e.g., integrated in) the system 565. Illustrative input devices 560 include a microphone, mouse, keyboard, joystick, game pad, game controller, satellite dish, scanner, printer, wireless device, etc. The input devices 560 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the system 565. The system 565 may be include depth cameras, such as stereoscopic camera systems, infrared camera systems, RGB camera systems, touchscreen technology, and combinations of these, for gesture detection and recognition. Additionally, the system 565 may include accelerometers or gyroscopes (e.g., as part of an inertia measurement unit (IMU)) that enable detection of motion. In some examples, the output of the accelerometers or gyroscopes may be used by the system 565 to render immersive augmented reality or virtual reality.

Further, the system 565 may be coupled to a network (e.g., a telecommunications network, local area network (LAN), wireless network, wide area network (WAN) such as the Internet, peer-to-peer network, cable network, or the like) through a network interface 535 for communication purposes. The system 565 may be included within a distributed network and/or cloud computing environment.

The network interface 535 may include one or more receivers, transmitters, and/or transceivers that enable the system 565 to communicate with other computing devices via an electronic communication network, included wired and/or wireless communications. The network interface 535 may be implemented as a network interface controller (NIC) that includes one or more data processing units (DPUs) to perform operations such as (for example and without limitation) packet parsing and accelerating network processing and communication. The network interface 535 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The system 565 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner. The system 565 may also include a hard-wired power supply, a battery power supply, or a combination thereof (not shown). The power supply may provide power to the system 565 to enable the components of the system 565 to operate.

Each of the foregoing modules and/or devices may even be situated on a single semiconductor platform to form the system 565. Alternately, the various modules may also be situated separately or in various combinations of semiconductor platforms per the desires of the user. While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the processing system 500 of FIG. 4 and/or exemplary system 565 of FIG. 5A—e.g., each device may include similar components, features, and/or functionality of the processing system 500 and/or exemplary system 565.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example processing system 500 of FIG. 4 and/or exemplary system 565 of FIG. 5A. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

### Machine Learning

Deep neural networks (DNNs) developed on processors, such as the PPU 400 have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron is the most basic model of a neural network. In one example, a neuron may receive one or more inputs that represent various features of an object that the neuron is being trained to recognize and classify, and each of these features is assigned a certain weight based on the importance of that feature in defining the shape of an object.

A deep neural network (DNN) model includes multiple layers of many connected nodes (e.g., neurons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions that are supported by the PPU 400. Inferencing is less compute-intensive than training, being a latency-sensitive process where a trained neural network is applied to new inputs it has not seen before to classify images, detect emotions, identify recommendations, recognize and translate speech, and generally infer new information.

Neural networks rely heavily on matrix math operations, and complex multi-layered networks require tremendous amounts of floating-point performance and bandwidth for both efficiency and speed. With thousands of processing cores, optimized for matrix math operations, and delivering tens to hundreds of TFLOPS of performance, the PPU 400 is a computing platform capable of delivering performance required for deep neural network-based artificial intelligence and machine learning applications.

Furthermore, images generated applying one or more of the techniques disclosed herein may be used to train, test, or certify DNNs used to recognize objects and environments in the real world. Such images may include scenes of roadways, factories, buildings, urban settings, rural settings, humans, animals, and any other physical object or real-world setting. Such images may be used to train, test, or certify DNNs that are employed in machines or robots to manipulate, handle, or modify physical objects in the real world. Furthermore, such images may be used to train, test, or certify DNNs that are employed in autonomous vehicles to navigate and move the vehicles through the real world. Additionally, images generated applying one or more of the techniques disclosed herein may be used to convey information to users of such machines, robots, and vehicles.

FIG. 5B illustrates components of an exemplary system 555 that can be used to train and utilize machine learning, in accordance with at least one embodiment. As will be discussed, various components can be provided by various combinations of computing devices and resources, or a single computing system, which may be under control of a single entity or multiple entities. Further, aspects may be triggered, initiated, or requested by different entities. In at least one embodiment training of a neural network might be instructed by a provider associated with provider environment 506, while in at least one embodiment training might be requested by a customer or other user having access to a provider environment through a client device 502 or other such resource. In at least one embodiment, training data (or data to be analyzed by a trained neural network) can be provided by a provider, a user, or a third party content provider 524. In at least one embodiment, client device 502 may be a vehicle or object that is to be navigated on behalf of a user, for example, which can submit requests and/or receive instructions that assist in navigation of a device.

In at least one embodiment, requests are able to be submitted across at least one network 504 to be received by a provider environment 506. In at least one embodiment, a client device may be any appropriate electronic and/or computing devices enabling a user to generate and send such requests, such as, but not limited to, desktop computers, notebook computers, computer servers, smartphones, tablet computers, gaming consoles (portable or otherwise), computer processors, computing logic, and set-top boxes. Network(s) 504 can include any appropriate network for transmitting a request or other such data, as may include Internet, an intranet, an Ethernet, a cellular network, a local area network (LAN), a wide area network (WAN), a personal area network (PAN), an ad hoc network of direct wireless connections among peers, and so on.

In at least one embodiment, requests can be received at an interface layer 508, which can forward data to a training and inference manager 532, in this example. The training and inference manager 532 can be a system or service including hardware and software for managing requests and service corresponding data or content, in at least one embodiment, the training and inference manager 532 can receive a request to train a neural network, and can provide data for a request to a training module 512. In at least one embodiment, training module 512 can select an appropriate model or neural network to be used, if not specified by the request, and can train a model using relevant training data. In at least one embodiment, training data can be a batch of data stored in a training data repository 514, received from client device 502, or obtained from a third party provider 524. In at least one embodiment, training module 512 can be responsible for training data. A neural network can be any appropriate network, such as a recurrent neural network (RNN) or convolutional neural network (CNN). Once a neural network is trained and successfully evaluated, a trained neural network can be stored in a model repository 516, for example, that may store different models or networks for users, applications, or services, etc. In at least one embodiment, there may be multiple models for a single application or entity, as may be utilized based on a number of different factors.

In at least one embodiment, at a subsequent point in time, a request may be received from client device 502 (or another such device) for content (e.g., path determinations) or data that is at least partially determined or impacted by a trained neural network. This request can include, for example, input data to be processed using a neural network to obtain one or more inferences or other output values, classifications, or predictions, or for at least one embodiment, input data can be received by interface layer 508 and directed to inference module 518, although a different system or service can be used as well. In at least one embodiment, inference module 518 can obtain an appropriate trained network, such as a trained deep neural network (DNN) as discussed herein, from model repository 516 if not already stored locally to inference module 518. Inference module 518 can provide data as input to a trained network, which can then generate one or more inferences as output. This may include, for example, a classification of an instance of input data. In at least one embodiment, inferences can then be transmitted to client device 502 for display or other communication to a user. In at least one embodiment, context data for a user may also be stored to a user context data repository 522, which may include data about a user which may be useful as input to a network in generating inferences, or determining data to return to a user after obtaining instances. In at least one embodiment, relevant data, which may include at least some of input or inference data, may also be stored to a local database 534 for processing future requests. In at least one embodiment, a user can use account information or other information to access resources or functionality of a provider environment. In at least one embodiment, if permitted and available, user data may also be collected and used to further train models, in order to provide more accurate inferences for future requests. In at least one embodiment, requests may be received through a user interface to a machine learning application 526 executing on client device 502, and results displayed through a same interface. A client device can include resources such as a processor 528 and memory 562 for generating a request and processing results or a response, as well as at least one data storage element 552 for storing data for machine learning application 526.

In at least one embodiment a processor 528 (or a processor of training module 512 or inference module 518) will be a central processing unit (CPU). As mentioned, however, resources in such environments can utilize GPUs to process data for at least certain types of requests. With thousands of cores, GPUs, such as PPU 400 are designed to handle substantial parallel workloads and, therefore, have become popular in deep learning for training neural networks and generating predictions. While use of GPUs for offline builds has enabled faster training of larger and more complex models, generating predictions offline implies that either request-time input features cannot be used or predictions must be generated for all permutations of features and stored in a lookup table to serve real-time requests. If a deep learning framework supports a CPU-mode and a model is small and simple enough to perform a feed-forward on a CPU with a reasonable latency, then a service on a CPU instance could host a model. In this case, training can be done offline on a GPU and inference done in real-time on a CPU. If a CPU approach is not viable, then a service can run on a GPU instance. Because GPUs have different performance and cost characteristics than CPUs, however, running a service that offloads a runtime algorithm to a GPU can require it to be designed differently from a CPU based service.

In at least one embodiment, video data can be provided from client device 502 for enhancement in provider environment 506. In at least one embodiment, video data can be processed for enhancement on client device 502. In at least one embodiment, video data may be streamed from a third party content provider 524 and enhanced by third party content provider 524, provider environment 506, or client device 502. In at least one embodiment, video data can be provided from client device 502 for use as training data in provider environment 506. In at least one embodiment, supervised and/or unsupervised training can be performed by the client device 502 and/or the provider environment 506. In at least one embodiment, a set of training data 514 (e.g., classified or labeled data) is provided as input to function as training data.

In at least one embodiment, training data can include instances of at least one type of object for which a neural network is to be trained, as well as information that identifies that type of object. In at least one embodiment, training data might include a set of images that each includes a representation of a type of object, where each image also includes, or is associated with, a label, metadata, classification, or other piece of information identifying a type of object represented in a respective image. Various other types of data may be used as training data as well, as may include text data, audio data, video data, and so on. In at least one embodiment, training data 514 is provided as training input to a training module 512. In at least one embodiment, training module 512 can be a system or service that includes hardware and software, such as one or more computing devices executing a training application, for training a neural network (or other model or algorithm, etc.). In at least one embodiment, training module 512 receives an instruction or request indicating a type of model to be used for training, in at least one embodiment, a model can be any appropriate statistical model, network, or algorithm useful for such purposes, as may include an artificial neural network, deep learning algorithm, learning classifier, Bayesian network, and so on. In at least one embodiment, training module 512 can select an initial model, or other untrained model, from an appropriate repository 516 and utilize training data 514 to train a model, thereby generating a trained model (e.g., trained deep neural network) that can be used to classify similar types of data, or generate other such inferences. In at least one embodiment where training data is not used, an appropriate initial model can still be selected for training on input data per training module 512.

In at least one embodiment, a model can be trained in a number of different ways, as may depend in part upon a type of model selected. In at least one embodiment, a machine learning algorithm can be provided with a set of training data, where a model is a model artifact created by a training process. In at least one embodiment, each instance of training data contains a correct answer (e.g., classification), which can be referred to as a target or target attribute. In at least one embodiment, a learning algorithm finds patterns in training data that map input data attributes to a target, an answer to be predicted, and a machine learning model is output that captures these patterns. In at least one embodiment, a machine learning model can then be used to obtain predictions on new data for which a target is not specified.

In at least one embodiment, training and inference manager 532 can select from a set of machine learning models including binary classification, multiclass classification, generative, and regression models. In at least one embodiment, a type of model to be used can depend at least in part upon a type of target to be predicted.

### Graphics Processing Pipeline

In an embodiment, the PPU 400 comprises a graphics processing unit (GPU). The PPU 400 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The PPU 400 can be configured to process the graphics primitives to generate a frame buffer (e.g., pixel data for each of the pixels of the display).

An application writes model data for a scene (e.g., a collection of vertices and attributes) to a memory such as a system memory or memory 404. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the processing units within the PPU 400 including one or more of a vertex shader, hull shader, domain shader, geometry shader, and a pixel shader. For example, one or more of the processing units may be configured to execute a vertex shader program that processes a number of vertices defined by the model data. In an embodiment, the different processing units may be configured to execute different shader programs concurrently. For example, a first subset of processing units may be configured to execute a vertex shader program while a second subset of processing units may be configured to execute a pixel shader program. The first subset of processing units processes vertex data to produce processed vertex data and writes the processed vertex data to the L2 cache and/or the memory 404. After the processed vertex data is rasterized (e.g., transformed from three-dimensional data into two-dimensional data in screen space) to produce fragment data, the second subset of processing units executes a pixel shader to produce processed fragment data, which is then blended with other processed fragment data and written to the frame buffer in memory 404. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

Images generated applying one or more of the techniques disclosed herein may be displayed on a monitor or other display device. In some embodiments, the display device may be coupled directly to the system or processor generating or rendering the images. In other embodiments, the display device may be coupled indirectly to the system or processor such as via a network. Examples of such networks include the Internet, mobile telecommunications networks, a WIFI network, as well as any other wired and/or wireless networking system. When the display device is indirectly coupled, the images generated by the system or processor may be streamed over the network to the display device. Such streaming allows, for example, video games or other applications, which render images, to be executed on a server, a data center, or in a cloud-based computing environment and the rendered images to be transmitted and displayed on one or more user devices (such as a computer, video game console, smartphone, other mobile device, etc.) that are physically separate from the server or data center. Hence, the techniques disclosed herein can be applied to enhance the images that are streamed and to enhance services that stream images such as NVIDIA GeForce Now (GFN), Google Stadia, and the like.

### Example Streaming System

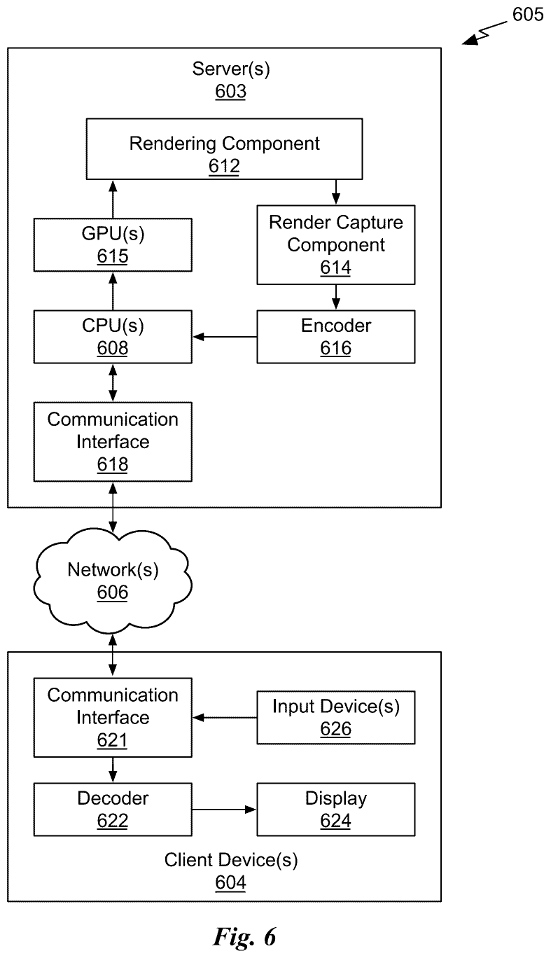

FIG. 6 is an example system diagram for a streaming system 605, in accordance with some embodiments of the present disclosure. FIG. 6 includes server(s) 603 (which may include similar components, features, and/or functionality to the example processing system 500 of FIG. 4 and/or exemplary system 565 of FIG. 5A), client device(s) 604 (which may include similar components, features, and/or functionality to the example processing system 500 of FIG. 4 and/or exemplary system 565 of FIG. 5A), and network(s) 606 (which may be similar to the network(s) described herein). In some embodiments of the present disclosure, the system 605 may be implemented.

In an embodiment, the streaming system 605 is a game streaming system and the server(s) 603 are game server(s). In the system 605, for a game session, the client device(s) 604 may only receive input data in response to inputs to the input device(s) 626, transmit the input data to the server(s) 603, receive encoded display data from the server(s) 603, and display the display data on the display 624. As such, the more computationally intense computing and processing is offloaded to the server(s) 603 (e.g., rendering - in particular ray or path tracing - for graphical output of the game session is executed by the GPU(s) 615 of the server(s) 603). In other words, the game session is streamed to the client device(s) 604 from the server(s) 603, thereby reducing the requirements of the client device(s) 604 for graphics processing and rendering.

For example, with respect to an instantiation of a game session, a client device 604 may be displaying a frame of the game session on the display 624 based on receiving the display data from the server(s) 603. The client device 604 may receive an input to one of the input device(s) 626 and generate input data in response. The client device 604 may transmit the input data to the server(s) 603 via the communication interface 621 and over the network(s) 606 (e.g., the Internet), and the server(s) 603 may receive the input data via the communication interface 618. The CPU(s) 608 may receive the input data, process the input data, and transmit data to the GPU(s) 615 that causes the GPU(s) 615 to generate a rendering of the game session. For example, the input data may be representative of a movement of a character of the user in a game, firing a weapon, reloading, passing a ball, turning a vehicle, etc. The rendering component 612 may render the game session (e.g., representative of the result of the input data) and the render capture component 614 may capture the rendering of the game session as display data (e.g., as image data capturing the rendered frame of the game session). The rendering of the game session may include ray or path-traced lighting and/or shadow effects, computed using one or more parallel processing units—such as GPUs, which may further employ the use of one or more dedicated hardware accelerators or processing cores to perform ray or path-tracing techniques—of the server(s) 603. The encoder 616 may then encode the display data to generate encoded display data and the encoded display data may be transmitted to the client device 604 over the network(s) 606 via the communication interface 618. The client device 604 may receive the encoded display data via the communication interface 621 and the decoder 622 may decode the encoded display data to generate the display data. The client device 604 may then display the display data via the display 624.

It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A method of configuring electrical circuit switches within a rack system including at least a first group of processors within a first enclosure and a second group of processors within a second enclosure, the first group of processors and the second group of processors each including at least one processor, the method comprising:
defining a first cluster that includes the first group of processors and a subset of the second group of processors;
configuring a first electrical circuit switch (ECS) within the first enclosure and a second ECS within the second enclosure to directly couple global connections between the first group and the subset, providing dedicated and independent communication paths between each one of the processors in the first cluster and other processors in the first cluster; and
transmitting a signal electronically from a first processor in the first group to a second processor in the subset through an electrical connection comprising one path of the dedicated and independent communication paths directly from the first ECS to the second ECS.

2. The method of claim 1, wherein the signal is transmitted only as an electrical current through the one path.

3. The method of claim 1, wherein the first ECS is configured to provide local dedicated and independent communication paths between each processor within the first group and every other processor within the first group.

4. The method of claim 1, wherein a portion of the first group and the subset is associated with a first slice of the first ECS and a first slice of the second ECS and a remaining portion of the first group and the subset is associated with a second slice of the first ECS and a second slice of the second ECS.

5. The method of claim 4, wherein the first ECS comprises an additional ECS that is subdivided into the first slice and the second slice to provide a portion of the global connections between the first group and the subset through a portion of the dedicated and independent communication paths directly from the additional ECS to the second ECS.

6. The method of claim 1, wherein a first processor within the first group is a spare processor.

7. The method of claim 6, further comprising
determining that a second processor in the first group has failed; and
configuring the first ECS to replace a first global connection of the global connections between the second processor and the subset with second global connection of the global connections between the first processor and the subset.

8. The method of claim 1, further comprising adding a third group of processors within a third enclosure to the first cluster by configuring the first ECS, the second ECS, and a third ECS within the third enclosure to provide additional global connections between the third group and the subset and between the third group and the first group to form a second cluster.

9. The method of claim 8, wherein the additional global connections are coupled through the first ECS to the second ECS.

10. The method of claim 1, further comprising removing the first group from the first cluster to form a second cluster that includes the subset and a third group of processors within a third enclosure by configuring the first ECS, the second ECS, and a third ECS within the third enclosure to provide additional global connections with the third group and the subset and remove a portion of the global connections between the first group and the subset.

11. The method of claim 1, further comprising configuring the first ECS and the second ECS to provide additional global connections with at least one group of processors in the second group of processors that is not included in the subset.

12. The method of claim 1, further comprising configuring the first ECS and the second ECS to remove the global connections between the first group and the subset.

13. The method of claim 1, wherein the first ECS is configured to provided additional dedicated and independent communication paths between processors in a second cluster that are separate from and support transmissions that occur simultaneously with transmissions on the dedicated and independent communication paths for the first cluster.

14. The method of claim 1, wherein local dedicated and independent communication paths between each processor within the first group and every other processor within the first group are hardwired without passing through the first ECS.

15. The method of claim 1, wherein at least one of the steps of defining, configuring, and transmitting are performed on a server or in a data center to transmit data and the data is streamed to a user device.

16. The method of claim 1, wherein at least one of the steps of defining, configuring, and transmitting is performed within a cloud computing environment.

17. The method of claim 1, wherein at least one of the steps of defining, configuring, and transmitting is performed for training, testing, or certifying a neural network employed in a machine, robot, or autonomous vehicle.

18. The method of claim 1, wherein at least one of the steps of defining, configuring, and transmitting is performed on a virtual machine comprising a portion of a graphics processing unit.

19. A rack system including a at least a first group of processors within a first enclosure and a second group of processors within a second enclosure, the first group of processors and the second group of processors each including at least one processor, the rack system comprising:
a first electrical circuit switch (ECS) within the first enclosure; and
a second ECS within the second enclosure, wherein the first ECS and the second ECS are configured to:
define a first cluster that includes the first group of processors and a subset of the second group of processors;
directly couple global connections between the first group and the subset, providing dedicated and independent communication paths between each one of the processors in the first cluster and other processors in the first cluster; and
transmit a signal electronically from a first processor in the first group to a second processor in the subset through an electrical connection comprising one path of the dedicated and independent communication paths directly from the first ECS to the second ECS.

20. The system of claim 19, wherein the signal is transmitted only as an electrical current through the one path.

21. A rack system including a first group of processors and a second group of processors within an enclosure, the first group of processors and the second group of processors each including at least one processor, the rack system comprising:
a first electrical circuit switch (ECS) within the enclosure; and
a second ECS within the enclosure, wherein the first ECS and the second ECS are configured to:
define a first cluster that includes the first group of processors and a subset of the second group of processors;
directly couple global connections between the first group and the subset, providing dedicated and independent communication paths between each one of the processors in the first cluster and other processors in the first cluster; and
transmit a signal electronically from a first processor in the first group to a second processor in the subset through an electrical connection comprising one path of the dedicated and independent communication paths directly from the first ECS to the second ECS.

22. The system of claim 21, wherein the signal is transmitted only as an electrical current through the one path.

23. The system of claim 21, further comprising configuring the first ECS and the second ECS to provide additional global connections with at least one group of processors in the second group of processors that is not included in the subset.
